(19) United States
(12) Patent Application Publication
(10) Pub. No.: US 2009/0250819 A1
(43) Pub. Date: Oct. 8, 2009

(54) METAL LINE OF SEMICONDUCTOR DEVICE AND METHOD OF FORMING THE SAME

(75) Inventor: Sang Deok Kim, Seoul (KR)

Correspondence Address: MARSHALL, GERSTEIN & BORUN LLP, 233 SOUTH WACKER DRIVE, 6300 SEARS TOWER, CHICAGO, IL, 60606-6357, US

(73) Assignee: HYNIX SEMICONDUCTOR INC., Icheon-si (KR)

(21) Appl. No.: 12/163,315

(22) Filed: Jun. 27, 2008

(30) Foreign Application Priority Data
Apr. 2, 2008 (KR) 10-2008-0030885

(51) Int. Cl. H01L 23/522; H01L 21/768

(52) U.S. Cl. 257/758; 438/633; 438/637; 257/E23.145; 257/E21.023; 257/E21.588; 257/E21.583; 257/E21.577

(57) ABSTRACT

The invention relates to a metal line of a semiconductor device and a method of forming the same. According to a method of forming a metal line of a semiconductor device in accordance with an aspect of the invention, a semiconductor substrate in which contact plugs are formed within contact holes of a first dielectric layer is first provided. An etch-stop layer and a hard mask pattern are formed over the first dielectric layer and the contact plugs. The etch-stop layer is patterned along the hard mask pattern. The exposed first dielectric layer and the contact plugs are etched to thereby form trenches in the first dielectric layer over the contact plugs. A metal layer is formed to gap-fill the trenches. A polishing process is performed to expose the etch-stop layer.

### CROSS-REFERENCES TO RELATED APPLICATIONS

Priority to Korean patent application number 10-2008-0030885, filed on Apr. 2, 2008, the disclosure of which is incorporated herein by reference in its entirety is claimed.

### BACKGROUND OF THE INVENTION

The invention relates to a metal line of a semiconductor device and a method of forming the same and, more particularly, to a metal line of a semiconductor device and a method of forming the same, which can shorten the turnaround time at the time of a polishing process and also improve the level of integration.

A semiconductor device includes a contact plug for electrically connecting lower structures (for example, junctions) and upper structures (for example, metal lines).

A semiconductor device including metal lines is described below in more detail.

A first dielectric layer is formed over a semiconductor substrate having junctions formed therein. Contact holes are formed in order to expose the junctions. The contact holes are gap-filled with a conductive layer to thereby form contact plugs. An etch-stop layer, which functions as an etch-stop layer when subsequent trenches are formed, is formed on the contact plugs and the first dielectric layer. A second dielectric layer for electrical insulation between adjacent metal lines is formed on the etch-stop layer. The second dielectric layer is generally formed of an oxide layer. The second dielectric layer is etched to thereby expose the etch-stop layer. An over-etch process is performed to thereby form trenches through which the contact plugs are exposed. The trenches are gap-filled with a metal layer, thus forming metal lines.

In particular, in order to make the metal lines along a pattern short, a polishing process for exposing the second dielectric layer is carried out. The polishing process is generally performed using an acid slurry that includes a silica abrasive. Different slurries can be used depending on the material of the target polishing subject. For example, in a polishing process of a tungsten (W) metal line, acid slurry, that is, silica abrasive can be used. Further, when the target polishing subject is multi-layered, a polishing process can be performed using a slurry having a high etch selectivity with respect to each layer. If respective polishing processes are performed ex-situ on target polishing subjects, the turnaround time and expenses can be increased. Further, if a slurry having a good etch selectivity with respect to the second dielectric layer, that is, an oxide layer, is used, the height of the second dielectric layer functioning to insulate a space between adjacent metal lines can become irregular. Consequently, a process of forming a subsequent layer may become difficult due to a difference in the height.

Further, if a nitride layer for an etch-stop layer remains between the metal lines, the nitride layer has a high dielectric constant. Accordingly, the entire capacitance of a semiconductor device can be increased.

### BRIEF SUMMARY OF THE INVENTION

The invention is directed to a metal line of a semiconductor device and a method of forming the same, in which when metal lines are formed, a polishing process can be performed in-situ using a slurry, for example, in which a silica abrasive and a cerium oxide abrasive, are mixed, the number of the processes of forming a dielectric layer can be reduced, and time and expense required for the fabrication process can be reduced.

A semiconductor device according to an aspect of the invention includes a semiconductor substrate in which junctions are formed, a first dielectric layer, in which contact holes are formed, formed on the semiconductor substrate, contact plugs contacting the junctions and formed in contact holes of the first dielectric layer, a metal line formed over one of the contact plugs, the metal line having a top surface protruding higher than a top surface of the first dielectric layer, and a second dielectric layer formed on the first dielectric layer and the metal line. The semiconductor device can include at least two adjacent metal lines.

A space between adjacent metal lines is insulated by the first dielectric layer and the second dielectric layer. The first dielectric layer and the second dielectric layer can be formed, for example, of a high density plasma (HDP) layer, a boro-phospho-silicate-glass (BPSG) layer, or a spin on dielectric (SOD) layer.

According to a method of forming a metal line of a semiconductor device in accordance with another aspect of the invention, a semiconductor substrate in which contact plugs are formed within contact holes of a first dielectric layer is provided. An etch-stop layer and a hard mask pattern are formed over the first dielectric layer and the contact plugs. The etch-stop layer is patterned along the hard mask pattern to expose a portion of the first-dielectric layer. The exposed first dielectric layer and the contact plugs are etched to thereby form trenches in the first dielectric layer over the contact plugs. A metal layer is formed to gap-fill the trenches. A polishing process is performed on the metal layer to expose the etch-stop layer.

The polishing process can be performed using a chemical mechanical polishing (CMP) process. The polishing process can be performed using slurry in which an acidic abrasive and a neutral abrasive are mixed.

The acidic abrasive can comprise a silica abrasive. The neutral abrasive can comprise a cerium oxide (CeO₂) abrasive. The acidic abrasive and the neutral abrasive can be mixed in a ratio in a range of 3:7 to 7:3.

The method can further include providing the semiconductor substrate having junctions formed therein, forming the first dielectric layer on the semiconductor substrate, forming the contact holes in the first dielectric layer so that the junctions are exposed, and gap-filling the contact holes with a conductive layer to form the contact plugs.

The etch-stop layer can be formed of a nitride. The hard mask pattern can be formed of an amorphous carbon. The metal layer can be formed of tungsten (W).

The formation of the trenches can be performed using a dry etch process. The dry etch process can be performed using a CH₂F₂ or CHF₃ gas as an etch gas.

After the polishing process is performed, the etch-stop layer is removed such that a top surface of the metal layer formed in the trenches protrudes higher than the first dielectric layer, and a second dielectric layer is formed on the metal layer and the first dielectric layer.

The removal of the etch-stop layer can be performed using a wet etch process. The wet etch process can be performed, for example using phosphoric acid (H₃PO₄) as an etchant.

The first dielectric layer and the second dielectric layer can be formed, for example, of a HDP layer, a BPSG layer, or a SOD layer.

According to a method of forming a metal line of a semiconductor device in accordance with still another aspect of the invention, a first dielectric layer is first formed on a semiconductor substrate. An etch-stop layer is formed on the first dielectric layer. Trenches are formed by etching the etch-stop layer and the first dielectric layer. A metal layer is formed in order to gap-fill the trenches. A polishing process is performed using slurry, in which a silica abrasive and a cerium oxide (CeO₂) abrasive are mixed, for example, to expose the etch-stop layer. The etch-stop layer can then be removed.

The slurry can be formed, for example, by mixing the silica abrasive and the cerium oxide (CeO₂) abrasive in a ratio in a range of 3:7 to 7:3.

The etch-stop layer can be formed of a nitride and the metal layer can be formed of tungsten (W).

The etch-stop layer can then be removed, a second dielectric layer can be formed on the metal layer and the first dielectric layer.

### BRIEF DESCRIPTION OF THE DRAWINGS

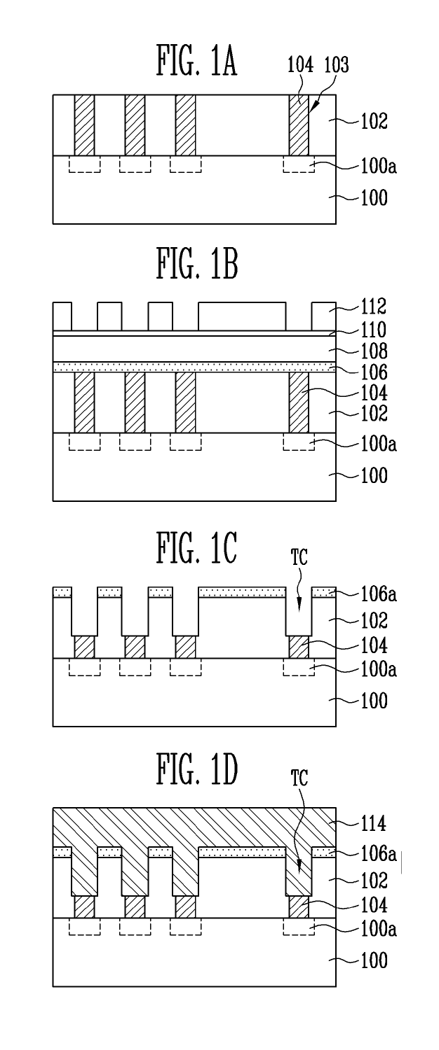

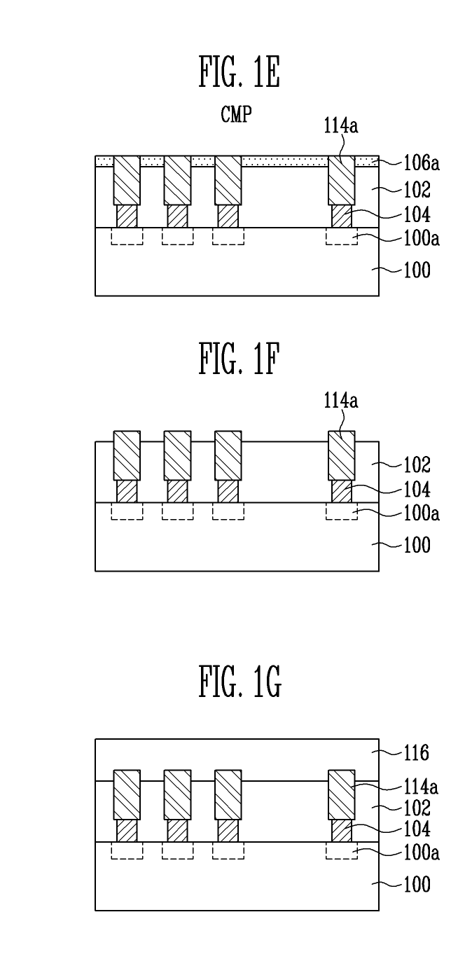

For a more complete understanding of the disclosure, reference should be made to the following detailed description and accompanying drawings. FIGS. 1A to 1G are sectional views illustrating a metal line of a semiconductor device in accordance with the invention.

### DESCRIPTION OF SPECIFIC EMBODIMENTS

Now, specific embodiments of the invention will be described with reference to the accompanying drawings.

However, the invention is not limited to the disclosed embodiments, but may be implemented in various manners. The embodiments are provided to complete the disclosure of the invention. The invention is defined by the category of the claims.

FIGS. 1A to 1G are sectional views illustrating metal lines of a semiconductor device in accordance with the invention.

Referring to FIG. 1A, a semiconductor substrate 100 having junctions 100a formed therein is provided. The junctions 100a are formed in regions of the semiconductor substrate 100, in which contact plugs 104 will be formed. A first dielectric layer 102 is formed on the semiconductor substrate 100 including the junctions 100a. The first dielectric layer 102 can be formed, for example, using a high density plasma (HDP) layer, a boro-phospho-silicate-glass (BPSG) layer, or a spin on dielectric (SOD) layer. A thickness of the first dielectric layer 102 is formed by considering the height of metal lines 114a to be formed subsequently. For example, the first dielectric layer 102 can be formed to a thickness in a range of 100 to 1000 angstroms.

Next, an etch process is performed on the first dielectric layer 102 to expose the junctions 100a, thereby forming contact holes 103. After the contact holes 103 are formed, an ion implantation process may be additionally performed on the junctions 100a in order to improve the electrical properties of the junctions 100a. The contact holes 103 are gap-filled with a conductive material to form contact plugs 104.

Referring to FIG. 1B, an etch-stop layer 106 is formed on the first dielectric layer 102 and the contact plugs 104. A hard mask layer 108 is formed on the etch-stop layer 106. A bottom anti-reflective coating (BARC) layer 110 and a photoresist pattern 112 for patterning the metal lines 114a are sequentially formed over the hard mask layer 108. The etch-stop layer 106 can be used, for example, as a stop layer in a subsequent polishing process. The etch-stop layer 106 can be formed, for example, of a nitride, which can be easily removed using an etchant (for example, phosphoric acid). The etch-stop layer 106 can be formed, for example, to a thickness in a range of 100 to 500 angstroms. Further, the hard mask layer 108 can be formed, for example, of amorphous carbon, and the BARC layer 110 can be formed, for example, of SiON.

Referring to FIG. 1C, the BARC layer 110 and the hard mask layer 108 are patterned by performing an etch process along the photoresist pattern 112. The etch-stop layer 106 is patterned along the patterned hard mask layer 108 to form an etch-stop pattern 106a. An etch process for removing a part of the first dielectric layer 102 and the contact plugs 104 is performed to form trenches TC. The first dielectric layer 102 and the contact plugs 104 are exposed along the patterned hard mask layer 108 and the etch-stop pattern 106a.

The etch process is preferably performed under the condition that the first dielectric layer 102 and the contact plugs 104 have the same etch selectivity. For example, the etch process can be performed using a CH₂F₂ or CHF₃ gas as an etch gas.

In particular, in NAND flash devices, the thickness of a metal Ml (for example, a metal line contacting a top surface of a drain contact plug) is approximately 1000 angstroms or less. Thus, although an etch process for forming contact holes 103 is performed using one condition without an etch-stop layer 106, the uniformity of the height of a semiconductor device is not affected.

Referring to FIG. 1D, the trenches TC are gap-filled with a metal layer 114. To fully gap-fill the trenches TC, the metal layer 114 is formed to a thickness sufficient enough to cover a top surface of the etch-stop pattern 106a. Preferably, the metal layer 114 is formed of tungsten (W). For example, the metal layer 114 can be formed by injecting a WF₆ gas, in a temperature in a range of 270 to 500 degrees Celsius, in a chamber.

Referring to FIG. 1E, a polishing process is performed to expose the etch-stop pattern 106a. Preferably, the polishing process is performed using a chemical mechanical polishing (CMP) process. The CMP process can be performed, for example, under a condition that has an etch selectivity higher with respect to the metal layer 114 than the etch-stop pattern 106a. The polishing process can be performed, for example, using a slurry in which a silica abrasive and a cerium oxide (CeO₂) abrasive are mixed.

An acidic silica abrasive can be used to remove tungsten (W). A neutral cerium oxide abrasive can be used to selectively remove an oxide layer, without significantly removing a nitride layer. Thus, if the weak acid slurry, in which the silica abrasive and the cerium oxide abrasive are mixed, is used, the metal layer 114 can be removed in-situ, but the polishing process can be stopped when the etch-stop pattern 106a is exposed. Preferably, the silica abrasive and the cerium oxide abrasive are mixed in a ratio in a range of 3:7 to 7:3. As the neutral abrasive and the acidic abrasive are mixed, a weakly acidic slurry is formed. Due to this, the time of the polishing process can be controlled, and a difference in the height of the metal lines 114a formed within the trenches TC can be reduced.

Referring to FIG. 1F, an etch process for removing the etch-stop pattern 106a is carried out. The etch process can be performed, for example, using a wet etch process. More specifically, the wet etch process can be performed, for example, using phosphoric acid (H₃PO₄) as an etchant. Accordingly, the etch-stop pattern 106a can be removed selectively, so that the metal lines 114a protrude upwardly from the first dielectric layer 102.

Referring to FIG. 1G, in order to electrically insulate between adjacent metal lines 114a, a second dielectric layer 216 is formed on the metal lines 114a and the first dielectric layer 102. The second dielectric layer 216 can be formed of a HDP layer, a BPSG layer, or a SOD layer.

As described above, since there is no nitride layer, having a dielectric constant higher than that of an oxide layer, between adjacent metal lines 114a, capacitance between the adjacent metal lines 114a can be lowered. Thus, when a semiconductor device is operated, RC delay can be prohibited and an interference phenomenon between neighboring metal lines 114a can be prevented. Accordingly, reliability of the semiconductor device can be improved. Further, the height of the contact plugs 104 is lowered, and the height of a semiconductor device is lowered due to the removal of the etch-stop layer 106. Accordingly, the level of integration can be improved.

As described above, according to the invention, when the metal lines 114a are formed, a polishing process can be performed in-situ using slurry in which silica abrasive and cerium oxide abrasive are mixed, and the number of the processes needed to form a dielectric layer can be reduced. Accordingly, time and expenses required for the fabrication process can be reduced.

Further, since the thickness of the dielectric layer can be reduced, the level of the integration of semiconductor device can be improved.

The embodiment disclosed herein has been proposed to allow a person skilled in the art to easily implement the present invention, and the person skilled in the art may implement the present invention in various ways. Therefore, the scope of the present invention is not limited by or to the embodiment as described above, and should be construed to be defined only by the appended claims and their equivalents.

What is claimed is:

1. A semiconductor device, comprising:
a semiconductor substrate in which junctions are formed;
a first dielectric layer, in which contact holes are formed, formed on the semiconductor substrate;
contact plugs contacting the junctions and formed in the contact holes of the first dielectric layer;
a metal line formed over one of the contact plugs, the metal line having a top surface protruding higher than a top surface of the first dielectric layer; and
a second dielectric layer formed on the first dielectric layer and the metal line.

2. The semiconductor device of claim 1, further comprising at least two adjacent metal lines.

3. The semiconductor device of claim 2, wherein a space between adjacent metal lines is insulated by the first dielectric layer and the second dielectric layer.

4. The semiconductor device of claim 3, wherein the first dielectric layer and the second dielectric layer are formed of a material selected from the group consisting of a high density plasma (HDP) layer, a boro-phospho-silicate-glass (BPSG) layer, and a spin on dielectric (SOD) layer.

5. A method of forming a metal line of a semiconductor device, the method comprising:
providing a semiconductor substrate in which contact plugs are formed within contact holes of a first dielectric layer;
forming an etch-stop layer and a hard mask pattern over the first dielectric layer and the contact plugs;
patterning the etch-stop layer along the hard mask pattern to expose a portion of the first dielectric layer, and etching the exposed first dielectric layer and the contact plugs to form trenches in the first dielectric layer over the contact plugs;
forming a metal layer to gap-fill the trenches; and
performing a polishing process on the metal layer to expose the etch-stop layer.

6. The method of claim 5, further comprising performing the polishing process using a chemical mechanical polishing (CMP) process.

7. The method of claim 5, further comprising performing the polishing process using a slurry in which an acidic abrasive and a neutral abrasive are mixed.

8. The method of claim 7, wherein the acidic abrasive comprises a silica abrasive.

9. The method of claim 7, wherein the neutral abrasive comprises a cerium oxide (CeO₂) abrasive.

10. The method of claim 7, wherein the acidic abrasive and the neutral abrasive are mixed in a ratio in a range of 3:7 to 7:3.

11. The method of claim 5, further comprising
providing the semiconductor substrate having junctions formed therein;
forming the first dielectric layer on the semiconductor substrate;
forming the contact holes in the first dielectric layer to expose the junctions; and
gap-filling the contact holes with a conductive layer to form the contact plugs.

12. The method of claim 5, further comprising forming the etch-stop layer of a nitride.

13. The method of claim 5, further comprising forming the hard mask pattern amorphous carbon.

14. The method of claim 5, further comprising forming the metal layer of tungsten (W).

15. The method of claim 5, further comprising forming of the trenches using a dry etch process.

16. The method of claim 15, further comprising performing the dry etch process using one of a CH₂F₂ and CHF₃ gas as an etch gas.

17. The method of claim 5, further comprising, after the polishing process is performed,
removing the etch-stop layer such that a top surface of the metal layer formed in the trenches is higher than the first dielectric layer; and
forming a second dielectric layer on the metal layer and the first dielectric layer.

18. The method of claim 17, further comprising removing the etch-stop layer using a wet etch process.

19. The method of claim 18, further comprising performing the wet etch process using phosphoric acid (H₃PO₄) as an etchant.

20. The method of claim 17, further comprising forming the first dielectric layer and the second dielectric layer of a material selected from the group consisting of a HDP layer, a BPSG layer, and a SOD layer.

21. A method of forming a metal line of a semiconductor device, the method comprising:
forming a first dielectric layer on a semiconductor substrate;
forming an etch-stop layer on the first dielectric layer;
etching the etch-stop layer and the first dielectric layer to form trenches;
gap-filling the trenches with a metal layer;
performing a polishing process on the metal layer using a slurry comprising a silica abrasive and a cerium oxide (CeO₂) abrasive to expose the etch-stop layer; and
removing the etch-stop layer.

22. The method of claim 21, wherein the slurry is formed by mixing the silica abrasive and the cerium oxide (CeO₂) abrasive in a ratio in a range of 3:7 to 7:3.

23. The method of claim 20, further comprising forming the etch-stop layer of a nitride.

24. The method of claim 20, further comprising forming the metal layer of tungsten (W).

25. The method of claim 20, further comprising, forming a second dielectric layer on the metal layer and the first dielectric layer, after the etch-stop layer is removed.
